(19) United States
(12) Patent Application Publication
(10) Pub. No.: US 2023/0231095 A1
(43) Pub. Date: Jul. 20, 2023

(54) DISPLAY DEVICE

(71) Applicant: Samsung Display Co., LTD., Yongin-si (KR)

(72) Inventor: JONGHYUN CHOI, Seoul (KR)

(73) Assignee: Samsung Display Co., LTD., Yongin-si (KR)

(21) Appl. No.: 18/076,539

(22) Filed: Dec. 7, 2022

(30) Foreign Application Priority Data
Jan. 18, 2022 (KR) 10-2022-0007264

(51) Int. Cl. H01L 33/62; H01L 33/38; H01L 27/15

(52) U.S. Cl. CPC H01L 33/62; H01L 33/382; H01L 27/156

(57) ABSTRACT

A display device includes a first semiconductor layer on a substrate, and including a first portion in a first pixel area, a second portion in a second pixel area, and a first connection portion connecting the first portion and the second portion, a second semiconductor layer on the first semiconductor layer, and including a first portion in the first pixel area, a second portion in the second pixel area, and a connection portion connecting the first portion and the second portion, a bias voltage line on the second semiconductor layer, electrically connected to the first connection portion of the first semiconductor layer, and extending in a second direction intersecting a first direction, and a reference voltage line on the second semiconductor layer, electrically connected to the connection portion of the second semiconductor layer, and extending in the second direction.

### CROSS-REFERENCE TO RELATED APPLICATION(S)

This application claims priority to and benefits of Korean Patent Application No. 10-2022-0007264 under 35 U.S.C. § 119, filed on Jan. 18, 2022 in the Korean Intellectual Property Office, the entire contents of which are incorporated herein by reference.

### BACKGROUND

### 1. Technical Field

Embodiments relate generally to a display device displaying a high-resolution image.

### 2. Description of the Related Art

A display device may include pixels, and may display an image by combining light emitted from the pixels.

Generally, the pixels may be disposed in a limited display area of the display device. As the number of pixels disposed in the display area increases, resolution of the image displayed on the display device may increase. Accordingly, in order to dispose as many pixels as possible in the display area, an area of each of the pixels must be reduced.

The pixel may include transistors for driving the pixel and signal lines providing driving signals to the transistors. As the number of transistors and the number of the signal lines increases, driving speed of the pixel may increase. However, as an area occupied by the transistors and an area occupied by the signal lines in the pixel increases, the area of pixel may be increase.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device including a pixel having a relatively small area and having a relatively high driving speed.

A display device according to an embodiment may include a first semiconductor layer disposed on a substrate, and including a first portion disposed in a first pixel area, a second portion disposed in a second pixel area, and a first connection portion connecting the first portion and the second portion, and the first portion and the second portion may have a shape symmetrical to each other based on a boundary between the first pixel area and the second pixel area; a second semiconductor layer disposed on the first semiconductor layer, and including a first portion disposed in the first pixel area, a second portion disposed in the second pixel area, and a connection portion connecting the first portion and the second portion, and the first portion and the second portion may have a shape symmetrical to each other based on the boundary between the first pixel area and the second pixel area; a bias voltage line disposed on the second semiconductor layer, electrically connected to the first connection portion of the first semiconductor layer, and extending in a second direction intersecting the first direction, and a reference voltage line disposed on the second semiconductor layer, electrically connected to the connection portion of the second semiconductor layer, and extending in the second direction.

According to an embodiment, the display device may further include a first gate electrode disposed on the first semiconductor layer, wherein a portion of the first gate electrode overlaps the first portion of the first semiconductor layer to define a first bias transistor in a plan view, and another portion of the first gate electrode overlaps the second portion of the first semiconductor layer to define a second bias transistor in the plan view.

According to an embodiment, the first connection portion of the first semiconductor layer may be a source area of the first bias transistor and a source area of the second bias transistor.

According to an embodiment, the display device may further include an emitting initialization control line disposed on the second semiconductor layer, extending in the first direction, and electrically connected to the first gate electrode.

According to an embodiment, the display device may further include an upper gate electrode disposed on the second semiconductor layer, a portion of the upper gate electrode overlaps the first portion of the second semiconductor layer to define a first reference transistor in a plan view, and another portion of the upper gate electrode overlaps the second portion of the second semiconductor layer to define a second reference transistor in the plan view.

According to an embodiment, the display device may further include a lower gate electrode disposed below the second semiconductor layer, a portion of the lower gate electrode overlaps the first portion of the second semiconductor layer and the portion of the upper gate electrode in the plan view, and another portion of the lower gate electrode overlaps the second portion of the second semiconductor layer and the another portion of the upper gate electrode in the plan view.

According to an embodiment, the connection portion of the second semiconductor layer may be a drain area of the first reference transistor and a drain area of the second reference transistor.

According to an embodiment, the display device may further include a reference voltage control line disposed on the second semiconductor layer, extending in the first direction, and electrically connected to the upper gate electrode.

According to an embodiment, the first semiconductor layer may include a silicon semiconductor, and the second semiconductor layer may include an oxide semiconductor.

According to an embodiment, the display device may further include an inorganic insulation layer disposed between the first semiconductor layer and the bias voltage line, and having a groove surrounding the first pixel area and the second pixel area.

According to an embodiment, the display device may further include an organic insulation layer disposed on the inorganic insulation layer, and filling the groove of the inorganic insulation layer.

A display device according to an embodiment may include a first semiconductor layer disposed on a substrate, and including a first portion disposed in a first pixel area, a second portion disposed in a second pixel area, and a first connection portion connecting the first portion and the second portion, the first portion and the second portion may have a shape symmetrical to each other based on a boundary between the first pixel area and the second pixel area; a second semiconductor layer disposed on the first semiconductor layer, and including a first portion disposed in the first pixel area, a second portion disposed in the second pixel area, a connection portion connecting the first portion and the second portion, a third portion disposed in the first pixel area, and a fourth portion disposed in the second pixel area and spaced apart from the third portion, the first portion and the second portion may have a shape symmetrical to each other based on the boundary between the first pixel area and the second pixel area, and the third portion and the fourth portion have a shape symmetrical to each other based on the boundary between the first pixel area and the second pixel area; a reference voltage line disposed on the second semiconductor layer, electrically connected to the connection portion of the second semiconductor layer, and extending in the second direction; and an initialization voltage line disposed on the second semiconductor layer, and electrically connected to the third portion of the second semiconductor layer and the fourth portion of the second semiconductor layer.

According to an embodiment, the initialization voltage line may include a horizontal initialization voltage line electrically connected to the third portion of the second semiconductor layer and the fourth portion of the second semiconductor layer, and extending in the first direction; and a vertical initialization voltage line electrically connected to the third portion of the second semiconductor layer.

According to an embodiment, the display device may further include a first bridge electrode disposed on the second semiconductor layer, electrically connecting the third portion of the second semiconductor layer and the first portion of the first semiconductor layer, and electrically connected to each of the horizontal initialization voltage line and the vertical initialization voltage line, and a second bridge electrode disposed on the second semiconductor layer, electrically connecting the fourth portion of the second semiconductor layer and the second portion of the first semiconductor layer, and electrically connected to the horizontal initialization voltage line.

A display device according to an embodiment may include a first semiconductor layer disposed on a substrate, and including a first portion disposed in a first pixel area, a second portion disposed in a second pixel area, a first connection portion connecting the first portion and the second portion, and a second connection portion connecting the first portion and the second portion and spaced apart from the first connection portion, the first portion and the second portion may have a shape symmetrical to each other based on a boundary between the first pixel area and the second pixel area; a bias voltage line disposed on the first semiconductor layer, electrically connected to the first connection portion of the first semiconductor layer, and extending in a second direction intersecting the first direction; and a power voltage line disposed on the first semiconductor layer, and electrically connected to the second connection portion of the first semiconductor layer.

According to an embodiment, the power voltage line may further include a horizontal power voltage line electrically connected to the second connection portion of the first semiconductor layer, and extending in the first direction; and a vertical power voltage line electrically contacting the horizontal power voltage line, and extending in the second direction.

According to an embodiment, the display device may further include a second gate electrode disposed on the first semiconductor layer, a portion of the second gate electrode overlaps the first portion of the first semiconductor layer to define a first emitting control transistor in a plan view, and another portion of the second gate electrode overlaps the second portion of the first semiconductor to define a second emitting control transistor in the plan view.

According to an embodiment, the second connection portion of the first semiconductor layer may be a source area of the first emitting control transistor and a source area of the second emitting control transistor.

According to an embodiment, the display device may further include a first hold capacitor lower electrode disposed in the first pixel area, and spaced apart from the second gate electrode; a second hold capacitor lower electrode disposed in the second pixel area, and spaced apart from the second gate electrode and the first hold capacitor lower electrode, the first hold capacitor lower electrode and the second hold capacitor lower electrode may have a shape symmetrical to each other based on the boundary between the first pixel area and the second pixel area, and a hold capacitor upper electrode disposed on the first hold capacitor lower electrode and the second hold capacitor lower electrode, and including a first portion overlapping the first hold capacitor lower electrode in a plan view, a second portion overlapping the second hold capacitor lower electrode in the plan view, and a connection portion connecting the first portion and the second portion.

According to an embodiment, the display device may further include a bridge electrode disposed on the hold capacitor upper electrode, connecting the hold capacitor upper electrode and the second connection portion of the first semiconductor layer, and electrically connected to the power voltage line.

In the display device according to an embodiment, the first portion of the first semiconductor layer and the second portion of the first semiconductor layer may share one bias voltage line, and the first portion of the second semiconductor layer and the second portion of the second semiconductor layer may share one reference voltage line.

In the display device according to an embodiment, the first portion of the second semiconductor layer and the second portion of the second semiconductor layer may share one reference voltage line, and the third portion of the second semiconductor layer and the fourth portion of the second semiconductor layer may share one initialization voltage line.

In the display device according to an embodiment, the first portion of the first semiconductor layer and the second portion of the first semiconductor layer may share one bias voltage line, and the first portion of the first semiconductor layer and the second portion of the first semiconductor layer may share one power voltage line.

It is to be understood that both the foregoing general description and the following detailed description are examples and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure together with the description.

FIG. 1 is a schematic plan view illustrating a display device according to an embodiment.

FIG. 2 is a schematic diagram of an equivalent circuit of a pixel included in the display device of FIG. 1.

FIG. 3, FIG. 4, FIG. 5, FIG. 6, FIG. 7, FIG. 8, FIG. 9, FIG. 10, and FIG. 11 are schematic diagrams illustrating a first pixel and a second pixel included in the display device of FIG. 1.

FIG. 12 is a schematic cross-sectional view taken along line I-I′ of FIG. 8 and FIG. 11.

FIG. 13 is a schematic cross-sectional view taken along line II-II′ of FIG. 8 and FIG. 11.

FIG. 14 is a schematic cross-sectional view taken along line III-III′ of FIG. 8 and FIG. 11.

FIG. 15 is a schematic cross-sectional view taken along line IV-IV′ of FIG. 8 and FIG. 11.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a schematic cross-sectional view” means viewing a cross-section of which the object is vertically cut from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

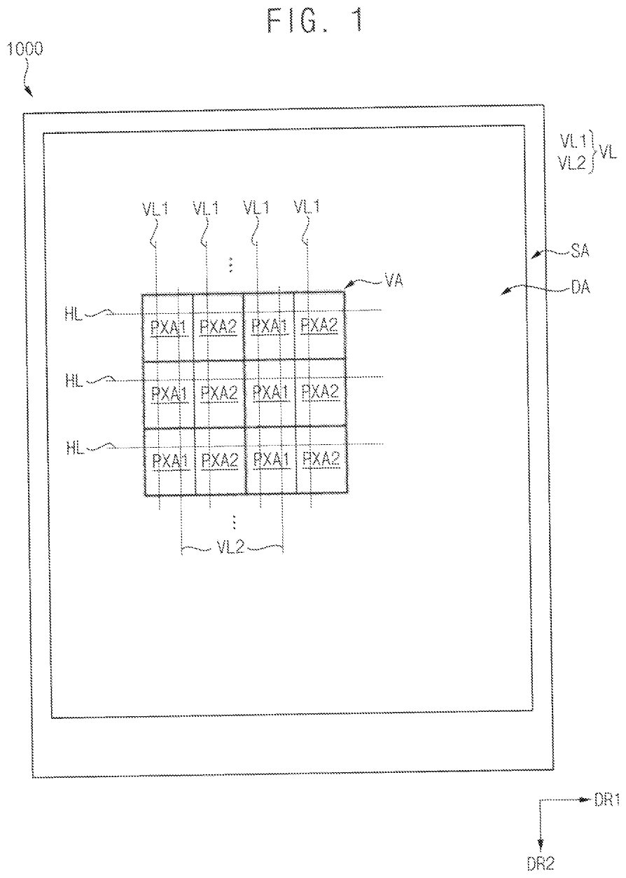

FIG. 1 is a schematic plan view illustrating a display device according to an embodiment.

Referring to FIG. 1, a display device 1000 according to an embodiment may include a display area DA and a peripheral area SA.

A pixel may be disposed in the display area DA. The pixel may emit light. The display device 1000 may display an image by combining light emitted from the pixel. The pixel may include a first pixel and a second pixel adjacent to the first pixel.

The display area DA may include a first pixel area PXA1 and a second pixel area PXA2. The first pixel area PXA1 and the second pixel area PXA2 may be alternately arranged or disposed along a first direction DR1 and a second direction DR2 intersecting the first direction DR1. The first pixel area PXA1 may be an area in which the first pixel is disposed, and the second pixel area PXA2 may be an area in which the second pixel is disposed.

Signal lines may be disposed in the first pixel area PXA1 and the second pixel area PXA2. For example, a horizontal signal line HL extending in the first direction DR1 and arranged or disposed in the second direction DR2, and a vertical signal line VL extending in the second direction DR2 and arranged or disposed in the first direction DR1 may be disposed in the first pixel area PXA1 and the second pixel area PXA2. The horizontal signal line HL and the vertical signal line VL may transmit a driving signal to the first pixel and the second pixel.

In an embodiment, the vertical signal line VL may include a first vertical signal line VL1 and a second vertical signal line VL2. Each of the first pixel and the second pixel may be electrically connected to the corresponding one first vertical signal line VL1. For example, the first pixel may be electrically connected to the first data line (for example, DATA-1 of FIG. 11), and the second pixel may be electrically connected to the second data line (for example, DATA-2 of FIG. 11). As an example, the first pixel and the second pixel may share one second vertical signal line VL2. For example, the first pixel and the second pixel may share a bias voltage line (for example, VBIAS of FIG. 11). For another example, the first pixel and the second pixel may share a reference voltage line (for example, VREF of FIG. 11).

As the first pixel and the second pixel share one second vertical signal line VL2, the number of second vertical signal lines VL2 required to drive the first pixel and the second pixel may be relatively reduced. Accordingly, an area occupied by the second vertical signal line VL2 may be relatively reduced, and thus, resolution of the display device 1000 may be relatively increased.

In an embodiment, a valley area VA may surround the first pixel area PXA1 and the second pixel area PXA2 adjacent to the first pixel area PXA1. The valley area VA may be an area for alleviating an impact caused by bending or deformation of the display device 1000.

The peripheral area SA may be adjacent to at least one side or a side of the display area DA. A driving part generating or transmitting the driving signal may be disposed in the peripheral area SA.

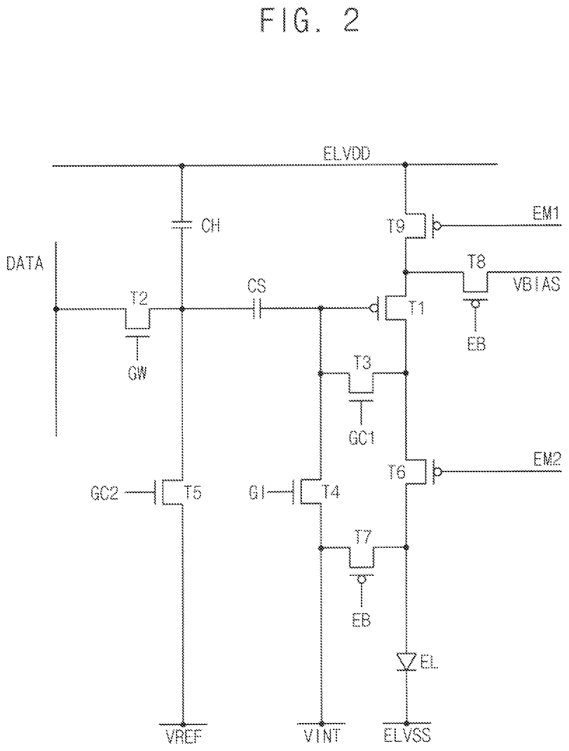

FIG. 2 is a schematic diagram of an equivalent circuit of a pixel included in the display device of FIG. 1.

Referring to FIG. 2, each of the first pixel and the second pixel may include a driving transistor T1, a switching transistor T2, a compensation transistor T3, an initialization transistor T4, a reference transistor T5, a control transistor T6, an emitting initialization transistor T7, a bias transistor T8, an emitting control transistor T9, a storage capacitor CS, a hold capacitor CH, and a light emitting diode EL. The light emitting diode EL may include an anode electrode and a cathode electrode. The cathode electrode of the light emitting diode EL may be electrically connected to a voltage line ELVSS.

The driving transistor T1 may be electrically connected between a power voltage line ELVDD and the anode electrode of the light emitting diode EL. A gate electrode of the driving transistor T1 may be electrically connected to a first electrode of the storage capacitor CS. The driving transistor T1 may provide a driving current corresponding a data signal provided by a data line DATA to the light emitting diode EL.

The switching transistor T2 may be electrically connected between the data line DATA and a second electrode of the storage capacitor CS. The switching transistor T2 may provide the data signal to the second electrode of the storage capacitor CS and a first electrode of the hold capacitor CH in response to a scan signal provided by a scan line GW.

The compensation transistor T3 may be electrically connected between the gate electrode of the driving transistor T1 and an output terminal of the driving transistor T1. The compensation transistor T3 may compensate a threshold voltage of the driving transistor T1 by diode-connecting the driving transistor T1 in response to a compensation control signal provided by a compensation control line GC1.

The initialization transistor T4 may be electrically connected between an initialization voltage line VINT and the first electrode of the storage capacitor CS. The initialization transistor T4 may provide an initialization voltage provided by the initialization voltage line VINT to the gate electrode of the driving transistor T1 in response to an initialization control signal provided by an initialization control line GI.

The reference transistor T5 may be electrically connected to a reference voltage line VREF and the second electrode of the storage capacitor CS. The reference transistor T5 may provide a reference voltage provided by the reference voltage line VREF to the second electrode of the storage capacitor CS and the first electrode of the hold capacitor CH in response to a reference voltage control signal provided by a reference voltage control line GC2.

The control transistor T6 may be electrically connected between the output terminal of the driving transistor T1 and the anode electrode of the light emitting diode EL. The control transistor T6 may provide the driving current to the light emitting diode EL in response to a second emitting control signal provided by the second emitting control line EM2.

The emitting initialization transistor T7 may be electrically connected between the initialization voltage line VINT and the anode electrode of the light emitting diode EL. The emitting initialization transistor T7 may provide the initialization voltage provided by the initialization voltage line VINT to the anode electrode of the light emitting diode EL in response to an emitting initialization control signal provided by an emitting initialization control line EB.

The bias transistor T8 may be electrically connected between a bias voltage line VBIAS and an input terminal of the driving transistor T1. The bias transistor T8 may provide a bias voltage provided by the bias voltage line VBIAS to the input terminal of the driving transistor T1 in response to the emitting initialization control signal provided by an emitting initialization control line EB.

The emitting control transistor T9 may be electrically connected between the power voltage line ELVDD and the input terminal of the driving transistor T1. The emitting control transistor T9 may provide a power voltage provided by the power voltage line ELVDD to the input terminal of the driving transistor T1 in response to a first emitting control signal provided by a first emitting control line EM1.

In an embodiment, the first emitting control signal and the second emitting control signal may have substantially the same signal waveform and different signal timings.

In an embodiment, the switching transistor T2, the compensation transistor T3, the initialization transistor T4, and the reference transistor T5 may include an oxide semiconductor. The switching transistor T2, the compensation transistor T3, the initialization transistor T4, and the reference transistor T5 may be NMOS transistor.

In an embodiment, the driving transistor T1, the control transistor T6, the emitting initialization transistor T7, the bias transistor T8, and the emitting control transistor T9 may include a silicon semiconductor. The driving transistor T1, the control transistor T6, the emitting initialization transistor T7, the bias transistor T8, and the emitting control transistor T9 may be PMOS transistor.

The storage capacitor CS may be electrically connected to the gate electrode of the driving transistor T1 and an output terminal of the switching transistor T2. The storage capacitor CS may maintain a voltage between the gate electrode of the driving transistor T1 and the output terminal of the switching transistor T2.

The hold capacitor CH may be electrically connected to the power voltage line ELVDD and the second electrode of the storage capacitor CS. The hold capacitor CH may maintain a voltage between the power voltage line ELVDD and the second electrode of the storage capacitor CS.

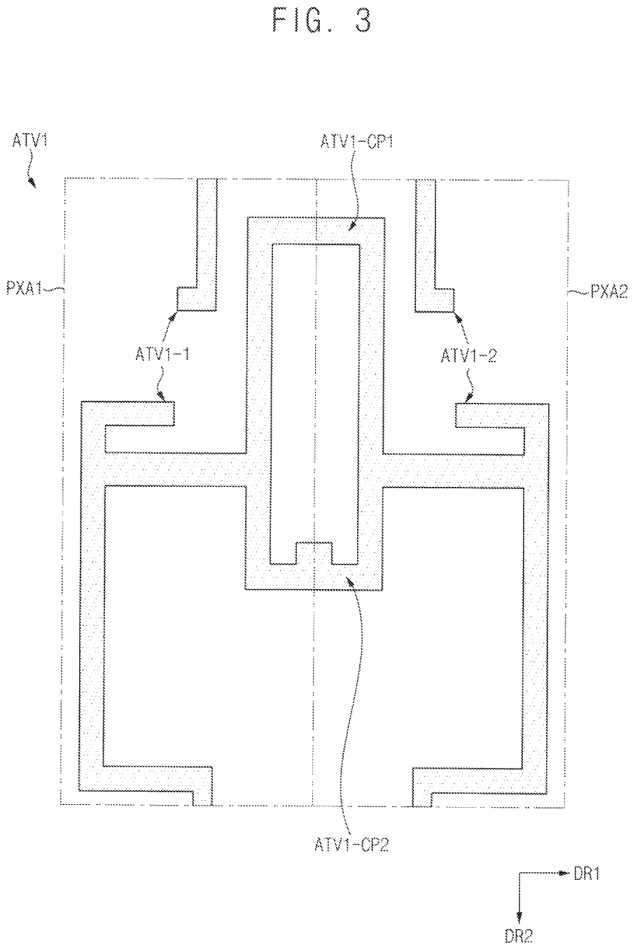

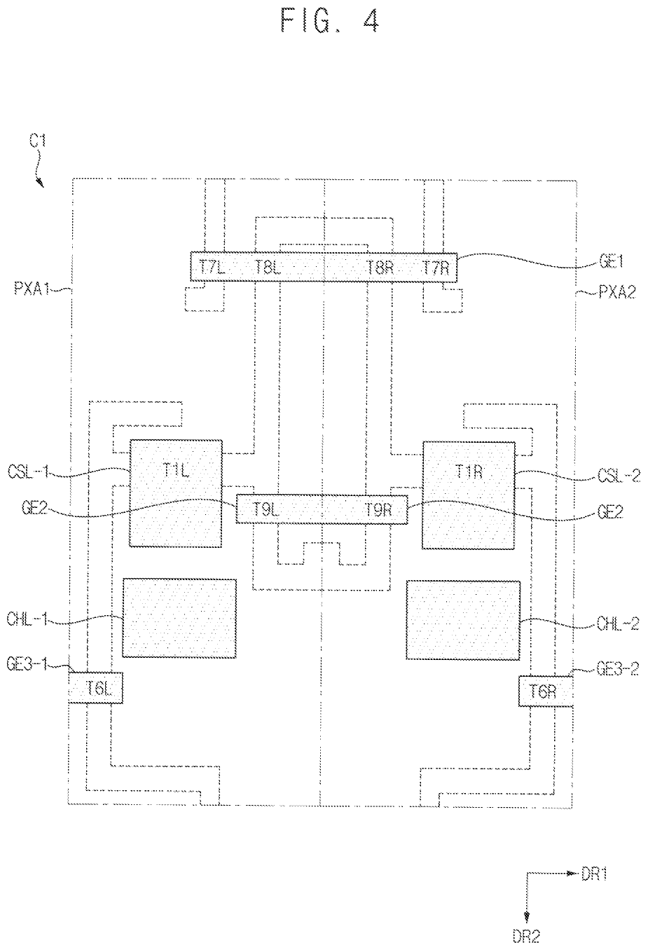

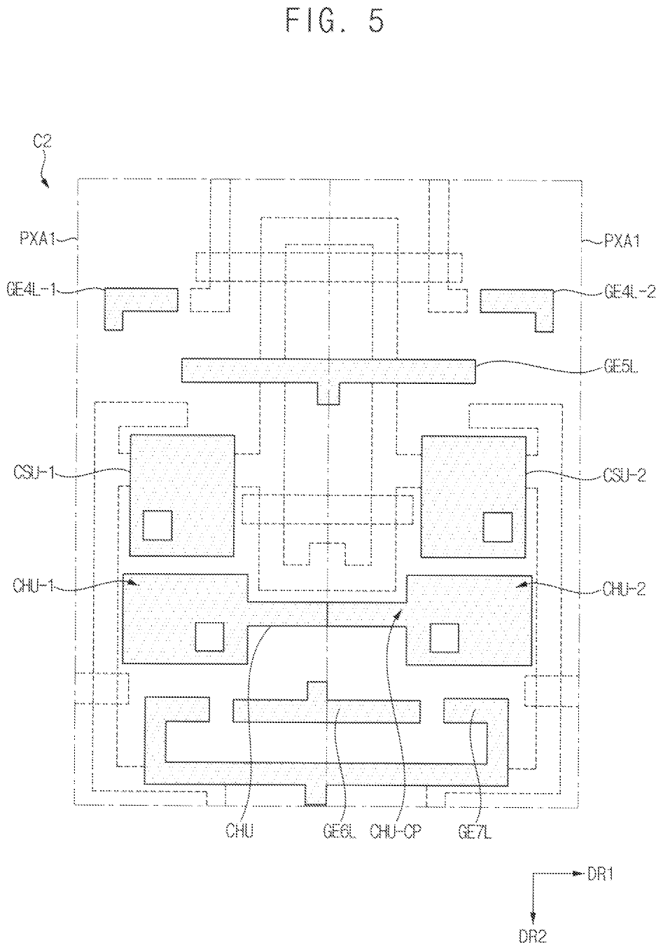

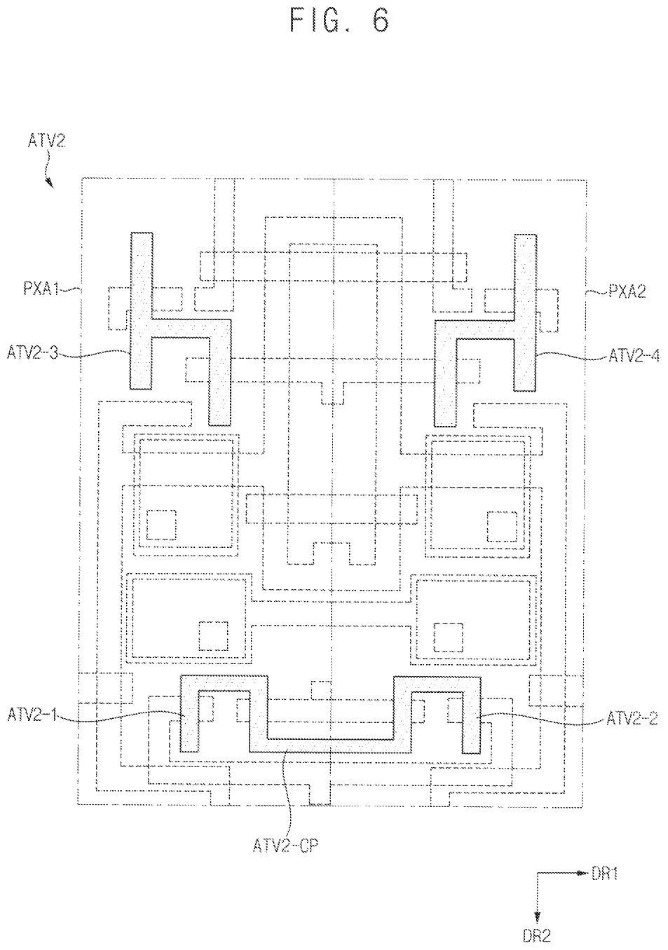

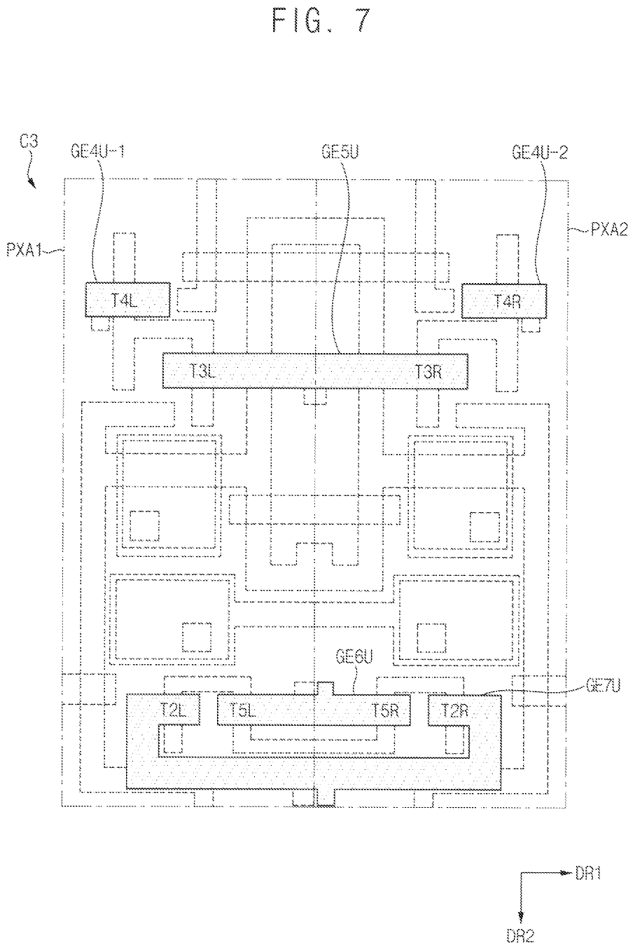

FIG. 3, FIG. 4, FIG. 5, FIG. 6, FIG. 7, FIG. 8, FIG. 9, FIG. 10, and FIG. 11 are schematic diagrams illustrating a first pixel and a second pixel included in the display device of FIG. 1.

Referring to FIG. 3, a first semiconductor layer ATV1 may be disposed in the first pixel area PXA1 and the second pixel area PXA2.

The first semiconductor layer ATV1 may include a first portion ATV1-1, a second portion ATV1-2, a first connection portion ATV1-CP1, and a second connection portion ATV1-CP2.

The first portion ATV1-1 may be disposed in the first pixel area PXA1. The second portion ATV1-2 may be disposed in the second pixel area PXA2. The first portion ATV1-1 and the second portion ATV1-2 may have a shape symmetrical to or a shape substantially symmetrical to each other based on a boundary between the first pixel area PXA1 and the second pixel area PXA2.

Each of the first connection portion ATV1-CP1 and the second connection portion ATV1-CP2 may connect the first portion ATV1-1 and the second connection portion ATV1-2. The first connection portion ATV1-CP1 and the second connection portion ATV1-CP2 may be spaced apart from each other.

In an embodiment, the first semiconductor layer ATV1 may include a silicon semiconductor material.

Referring to FIG. 4, a first conductive layer C1 may be disposed on the first semiconductor layer ATV1. The first conductive layer C1 may include a first gate electrode GE1, a second gate electrode GE2, a first storage capacitor lower electrode CSL-1, a second storage capacitor lower electrode CSL-2, a first hold capacitor lower electrode CHL-1, a second hold capacitor lower electrode CHL-2, and third gate electrodes GE3-1 and GE3-2.

A portion of the first gate electrode GE1 may overlap the first portion ATV1-1 of the first semiconductor layer ATV1. At the same time, another portion of the first gate electrode GE1 may overlap the second portion ATV1-2 of the first semiconductor layer ATV1.

The first gate electrode GE1 and the first portion ATV1-1 of the first semiconductor layer ATV1 may define a first emitting initialization transistor T7L and a first bias transistor T8L. The first gate electrode GE1 and the second portion ATV1-2 of the first semiconductor layer ATV1 may define a second emitting initialization transistor T7R and a second bias transistor T8R. A source area of the first bias transistor T8L and a source area of the second bias transistor T8R may be the first connection portion ATV1-CP1 of the first semiconductor layer ATV1.

A portion of the second gate electrode GE2 may overlap the first portion ATV1-1 of the first semiconductor layer ATV1. At the same time, another portion of the second gate electrode GE2 may overlap the second portion ATV1-2 of the first semiconductor layer ATV1.

The second gate electrode GE2 and the first portion ATV1-1 of the first semiconductor layer ATV1 may define a first emitting control transistor T9L. The second gate electrode GE2 and the second portion ATV1-2 of the first semiconductor layer ATV1 may define a second emitting control transistor T9R. A source area of the first emitting control transistor T9L and a source area of the second emitting control transistor T9R may be the second connection portion ATV1-CP2 of the first semiconductor layer ATV1.

A portion of the first storage capacitor lower electrode CSL-1 may overlap the first portion ATV1-1 of the first semiconductor layer ATV1. A portion of the second storage capacitor lower electrode CSL-2 may overlap the second portion ATV1-2 of the first semiconductor layer ATV1.

The first storage capacitor lower electrode CSL-1 and the first portion ATV1-1 of the first semiconductor layer ATV1 may define a first driving transistor T1L. The second storage capacitor lower electrode CSL-2 and the second portion ATV1-2 of the first semiconductor layer ATV1 may define the second driving transistor T1R.

The first hold capacitor lower electrode CHL-1 may be disposed in the first pixel area PXA1. The second hold capacitor lower electrode CHL-2 may be disposed in the second pixel area PXA2.

A portion of the third gate electrode GE3-1 disposed in the first pixel area PXA1 may overlap the first portion ATV1-1 of the first semiconductor layer ATV1. A portion of the third gate electrode GE3-2 disposed in the second pixel area PXA2 may overlap the second portion ATV1-2 of the first semiconductor layer ATV1.

The third gate electrode GE3-1 disposed in the first pixel area PXA1 and the first portion ATV1-1 of the first semiconductor layer ATV1 may define a first control transistor T6L. The third gate electrode GE3-2 disposed in the second pixel area PXA2 and the second portion ATV1-2 of the first semiconductor layer ATV1 may define a second control transistor T6R.

Referring to FIG. 5, a second conductive layer C2 may be disposed on the first conductive layer C1. The second conductive layer C2 may include fourth lower gate electrodes GE4L-1 and GE4L-2, a fifth lower gate electrode GE5L, a first storage capacitor upper electrode CSU-1, a second storage capacitor upper electrode CSU-2, a hold capacitor upper electrode CHU, a sixth lower gate electrode GE6L, and a seventh lower gate electrode GE7L.

The first storage capacitor upper electrode CSU-1 may overlap the first storage capacitor lower electrode CSL-1. The first storage capacitor upper electrode CSU-1 may define an opening exposing a portion of an upper surface of the first storage capacitor upper electrode CSU-1 in a plan view. The second storage capacitor upper electrode CSU-2 may overlap the second storage capacitor lower electrode CSL-2. The second storage capacitor upper electrode CSU-2 may define an opening exposing a portion of an upper surface of the second storage capacitor lower electrode CSL-2 in a plan view.

The first storage capacitor upper electrode CSU-1 and the first storage capacitor lower electrode CSL-1 may define a first storage capacitor. The first storage capacitor may be the storage capacitor CS disposed in the first pixel area PXA1. The second storage capacitor upper electrode CSU-2 and the second storage capacitor lower electrode CSL-2 may define a second storage capacitor. The second storage capacitor may be the storage capacitor CS disposed in the second pixel area PXA2.

The hold capacitor upper electrode CHU may include a first portion CHU-1, a second portion CHU-2, and a connection portion CHU-CP.

The first portion CHU-1 of the hold capacitor upper electrode CHU may overlap the first hold capacitor lower electrode CHL-1. The first portion CHU-1 of the hold capacitor upper electrode CHU may define an opening exposing a portion of an upper surface of the first hold capacitor lower electrode CHL-1 in a plan view. The second portion CHU-2 of the hold capacitor upper electrode CHU may overlap the second hold capacitor lower electrode CHL-2. The second portion CHU-2 of the hold capacitor upper electrode CHU may define an opening exposing a portion of an upper surface of the second hold capacitor lower electrode CHL-2. The connection portion CHU-CP of the hold capacitor upper electrode may connect the first portion CHU-1 of the hold capacitor upper electrode CHU and the second portion CHU-2 of the hold capacitor upper electrode CHU.

The first portion CHU-1 of the hold capacitor upper electrode CHU and the first hold capacitor lower electrode CHL-1 may define a first hold capacitor. The first hold capacitor may be the hold capacitor CH disposed in the first pixel area PXA1. The second portion CHU-2 of the hold capacitor upper electrode CHU and the second hold capacitor lower electrode CHL-2 may define a second hold capacitor. The second hold capacitor may be the hold capacitor CH disposed in the second pixel area PXA2.

Referring to FIG. 6, a second semiconductor layer ATV2 may be disposed on the second conductive layer C2.

The second semiconductor layer ATV2 may include a first portion ATV2-1, a second portion ATV2-2, a third portion ATV2-3, a fourth portion ATV2-4, and a connection portion ATV2-CP.

The first portion ATV2-1 may be disposed in the first pixel area PXA1. The second portion ATV2-2 may be disposed in the second pixel area PXA2. The first portion ATV2-1 and the second portion ATV2-2 may have a shape symmetrical to or a shape substantially symmetrical to each other based on the boundary between the first pixel area PXA1 and the second pixel area PXA2.

The connection portion ATV2-CP may connect the first portion ATV2-1 and the second portion ATV2-2.

The third portion ATV2-3 may be disposed in the first pixel area PXA1. The fourth portion ATV2-4 may be disposed in the second pixel area PXA2. The third portion ATV2-3 and the second portion ATV2-4 may be spaced apart from each other. The third portion ATV2-3 and the fourth portion ATV2-4 may have a shape symmetrical to or a shape substantially symmetrical to each other based on the boundary between the first pixel area PXA1 and the second pixel area PXA2.

In an embodiment, the second semiconductor layer ATV2 may include an oxide semiconductor material.

Referring again to FIG. 5 and FIG. 6, a portion of the fourth lower gate electrode GE4L-1 disposed in the first pixel area PXA1 may overlap the third portion ATV2-3 of the second semiconductor layer ATV2. A portion of the fourth lower gate electrode GE4L-2 disposed in the second pixel area PXA2 may overlap the fourth portion ATV2-4 of the second semiconductor layer ATV2.

A portion of the fifth lower gate electrode GE5L may overlap the third portion ATV2-3 of the second semiconductor layer ATV2. Another portion of the fifth lower gate electrode GE6L may overlap the fourth portion ATV2-4 of the second semiconductor layer ATV2.

A portion of the sixth lower gate electrode GE6L may overlap the first portion ATV2-1 of the second semiconductor layer ATV2. Another portion of the sixth lower gate electrode GE6L may overlap the second portion ATV2-2 of the second semiconductor layer ATV2.

A portion of the seventh lower gate electrode GE7L may overlap the first portion ATV2-1 of the second semiconductor layer ATV2. Another portion of the seventh lower gate electrode GE7L may overlap the second portion ATV2-2 of the second semiconductor layer ATV2.

Referring to FIG. 7, a third conductive layer C3 may be disposed on the second semiconductor layer ATV2. The third conductive layer C3 may include fourth upper gate electrodes GE4U-1 and GE4U-2, a fifth upper gate electrode GE5U, a sixth upper gate electrode GE6U, and a seventh upper gate electrode GE7U.

A portion of the fourth upper gate electrode GE4U-1 disposed in the first pixel area PXA1 may overlap the third portion ATV2-3 of the second conductive layer ATV2. A portion of the fourth upper gate electrode GE4U-2 disposed in the second pixel area PXA2 may overlap the fourth portion ATV2-4 of the second semiconductor layer ATV2.

The fourth upper gate electrode GE4U-1 disposed in the first pixel area PXA1, the fourth lower gate electrode GE4L-1 disposed in the first pixel area PXA1, and the third portion ATV2-3 of the second semiconductor layer ATV2 may define a first initialization transistor T4L. The fourth upper gate electrode GE4U-2 disposed in the second pixel area PXA2, the fourth lower gate electrode GE4L-2 disposed in the second pixel area PXA2, and the fourth portion ATV2-4 of the second semiconductor layer ATV2 may define a second initialization transistor T4R.

A portion of the fifth upper gate electrode GE5U may overlap the third portion ATV2-3 of the second semiconductor layer ATV2. Another portion of the fifth upper gate electrode GE5U may overlap the fourth portion ATV2-4 of the second semiconductor layer ATV2.

The fifth upper gate electrode GE5U, the fifth lower gate electrode GE5L, and the third portion ATV2-3 of the second semiconductor layer ATV2 may define a first compensation transistor T3L. The fifth upper gate electrode GE5U, the fifth lower gate electrode GE5L, and the fourth portion ATV2-4 of the second semiconductor layer ATV2 may define a second compensation transistor T3R.

A portion of the sixth upper gate electrode GE6U may overlap the first portion ATV2-1 of the second semiconductor layer ATV2. Another portion of the sixth upper gate electrode GE6U may overlap the second portion ATV2-2 of the second semiconductor layer ATV2.

The sixth upper gate electrode GE6U, the sixth lower gate electrode GE6L, and the first portion ATV2-1 of the second semiconductor layer ATV2 may define a first reference transistor T5L. The sixth upper gate electrode GE6U, the sixth lower gate electrode GE6L, and the second portion ATV2-2 of the second semiconductor layer ATV2 may define a second reference transistor T5R. A drain area of the first reference transistor T5L and a drain area of the second reference transistor T5R may be connection part ATV2-CP of the second semiconductor layer ATV2.

A portion of the seventh upper gate electrode GE7U may overlap the first portion ATV2-1 of the second semiconductor layer ATV2. Another portion of the seventh upper gate electrode GE7U may overlap the second portion ATV2-2 of the second semiconductor layer ATV2.

The seventh upper gate electrode GE7U, the seventh lower gate electrode GE7L, and the first portion ATV2-1 of the second semiconductor layer ATV2 may define a first switching transistor T2L. The seventh upper gate electrode GE7U, the seventh lower gate electrode GE7L, and the second portion ATV2-2 of the second semiconductor layer ATV2 may define a second switching transistor T2R.

Referring to FIG. 8, a fourth conductive layer C4 may be disposed on the third conductive layer C3. The fourth conductive layer C4 may include first to sixth bridge electrodes BR1-1, BR1-2, BR2, BR3, BR4-1, BR4-2, BR5, BR6-1, BR6-2, BR7-1, BR7-2, BR8, BR9-1, BR9-2, BR10, BR11-1, BR11-2, BR12, BR13-1, BR13-2, BR14, BR15-1, BR15-2, and BR16.

The first bridge electrode BR1-1 disposed in the first pixel area PXA1 may electrically connect a drain area of the first initialization transistor T4L and a source area of the first emitting initialization transistor T7L.

The first bridge electrode BR1-2 disposed in the second pixel area PXA2 may electrically connect a drain area of the first initialization transistor T4L and a source area of the first emitting initialization transistor T7L.

The second bridge electrode BR2 may electrically contact a source area of the first bias transistor T8L and a source area of the second bias transistor T8R. In other words, the second bridge electrode BR2 may electrically contact the first connection portion ATV1-CP1 of first semiconductor layer ATV1.

The third bridge electrode BR3 may electrically contact the first gate electrode GE1.

The fourth bridge electrode BR4-1 disposed in the first pixel area PXA1 may electrically connect the fourth upper gate electrode GE4U-1 disposed in the first pixel area PXA1 and the fourth lower gate electrode GE4L-1 disposed in the first pixel area PXA1.

The fourth bridge electrode BR4-2 disposed in the second pixel area PXA2 may electrically connect the fourth upper gate electrode GE4U-2 disposed in the second pixel area PXA2 and the fourth lower gate electrode GE4L-1 disposed in the second pixel area PXA2.

The fifth bridge electrode BR5 may electrically connect the fifth upper gate electrode GE5U and the fifth lower gate electrode GE5L.

The sixth bridge electrode BR6-1 disposed in the first pixel area PXA1 may electrically connect a source area of the first initialization transistor T4L, a source area of the first compensation transistor T3L, and the first storage capacitor lower electrode CSL-1.

The sixth bridge electrode BR6-2 disposed in the second pixel area PXA2 may electrically connect a source area of the second initialization transistor T4R, a source area of the second compensation transistor T3R, and the second storage capacitor lower electrode CSL-2.

The seventh bridge electrode BR7-1 disposed in the first pixel area PXA1 may electrically connect a drain area of the first driving transistor T1L, a source area of the first control transistor T6L, and a drain area of the first compensation transistor T3L.

The seventh bridge electrode BR7-2 disposed in the second pixel area PXA2 may electrically connect a drain area of the second driving transistor T1R, a source area of the second control transistor T6R, and a drain area of the second compensation transistor T3R.

The eight bridge electrode BR8 may electrically contact the second gate electrode GE2.

The ninth bridge electrode BR9-1 disposed in the first pixel area PXA1 may electrically connect the first storage capacitor upper electrode CSU-1, the first hold capacitor lower electrode CHL-1, a source area of the first switching transistor T2L, and a source area of the first reference transistor T5L.

The ninth bridge electrode BR9-2 disposed in the second pixel area PXA2 may electrically connect the second storage capacitor upper electrode CSU-2, the second hold capacitor lower electrode CHL-2, a source area of the second switching transistor T2R, and a source area of the second reference transistor T5R.

The tenth bridge electrode BR10 may electrically connect a source area of the first emitting control transistor T9L, a source area of the second emitting control transistor T9R, and the hold capacitor upper electrode CHU. In other words, the tenth bridge electrode BR10 may electrically contact the second connection portion ATV1-CP2 of the first active area ATV1, and the connection part CHU-CP of the hold capacitor upper electrode CHU.

The eleventh bridge electrode BR11-1 disposed in the first pixel area PXA1 may electrically contact the third gate electrode GE3-1 disposed in the first pixel area PXA1.

The eleventh bridge electrode BR11-2 disposed in the second pixel area PXA2 may electrically contact the third gate electrode GE3-2 disposed in the second pixel area PXA2.

The twelfth bridge electrode BR12 may electrically connect the sixth upper gate electrode GE6U and the sixth lower gate electrode GE6L.

The thirteenth bridge electrode BR13-1 disposed in the first pixel area PXA1 may electrically contact a drain area of the first control transistor T6L.

The thirteenth bridge electrode BR13-2 disposed in the second pixel area PXA2 may electrically contact a drain area of the second control transistor T6R.

The fourteenth bridge electrode BR14 may electrically contact a drain area of the first reference transistor T5L and a drain area of the second reference transistor T5R. In other words, the fourteen bridge electrode BR14 may be electrically contact the connection portion ACT2-CP of the second semiconductor layer ATV2.

The fifteenth bridge electrode BR15-1 disposed in the first pixel area PXA1 may electrically contact a drain area of the first switching transistor T2L.

The fifteenth bridge electrode BR15-2 disposed in the second pixel area PXA2 may electrically contact a drain area of the second switching transistor T2R.

The sixteenth bridge electrode BR16 may electrically connect the seventh upper gate electrode GE7U and the seventh lower gate electrode GE7L.

Referring to FIG. 9, a fifth conductive layer C5 may be disposed on the fourth conductive layer C4. The fifth conductive layer C5 may include seventeenth to twenty-fifth bridge electrodes BR17, BR18, BR19, BR20-1, BR20-2, BR21, BR22-1, BR22-2, BR23-1, BR23-2, BR24-1, BR24-2, and BR25, the initialization control line GI, the compensation control line GC1, the first emitting control line EM1, the reference voltage control line GC2, and the scan lien GW.

The seventeenth bridge electrode BR17 may electrically contact the second bridge electrode BR2.

The eighteenth bridge electrode BR18 may electrically contact the third bridge electrode BR3.

The nineteenth bridge electrode BR19 may electrically contact the first bridge electrode BR1-1 disposed in the first pixel area PXA1.

The twenty bridge electrode BR20-1 disposed in the first pixel area PXA1 may electrically contact the first bridge electrode BR1-1 disposed in the first pixel area PXA1.

The twenty bridge electrode BR20-2 disposed in the second pixel area PXA2 may electrically contact the first bridge electrode BR1-2 disposed in the second pixel area PXA2.

The twenty-first bridge electrode BR21 may electrically contact the tenth bridge electrode BR10.

The twenty-second bridge electrode BR22-1 disposed in the first pixel area PXA1 may electrically contact the eleventh bridge electrode BR11-1 disposed in the first pixel area PXA1.

The twenty-second bridge electrode BR22-2 disposed in the second pixel area PXA2 may electrically contact the eleventh bridge electrode BR11-2 disposed in the second pixel area PXA2.

The twenty-third bridge electrode BR23-1 disposed in the first pixel area PXA1 may electrically contact the thirteenth bridge electrode BR13-1 disposed in the first pixel area PXA1.

The twenty-third bridge electrode BR23-2 disposed in the second pixel area PXA2 may electrically contact the thirteenth bridge electrode BR13-2 disposed in the second pixel area PXA2.

The twenty-fourth bridge electrode BR24-1 disposed in the first pixel area PXA1 may electrically contact the fifteenth bridge electrode BR15-1 disposed in the first pixel area PXA1.

The twenty-fourth bridge electrode BR24-2 disposed in the second pixel area PXA2 may electrically contact the fifteenth bridge electrode BR15-2 disposed in the second pixel area PXA2.

The twenty-fifth bridge electrode BR25 may electrically contact the fourteenth bridge electrode BR14.

The initialization control line GI may extend in the first direction DR1. The initialization control line GI may electrically contact the fourth bridge electrodes BR4-1 and BR4-2. The initialization control line GI may provide the initialization control signal.

The compensation control line GC1 may extend in the first direction DR1. The compensation control line GC1 may electrically contact the fifth bridge electrode BRS. The compensation control line GC1 may provide the compensation control signal.

The first emitting control line EM1 may extend in the first direction DR1. The first emitting control line EM1 may electrically contact the eight bridge electrode BR8. The first emitting control line EM1 may provide the first emitting control signal.

The reference voltage control line GC2 may extend in the first direction DR1. The reference voltage control line GC2 may electrically contact the twelfth bridge electrode BR12. The reference voltage control line GC2 may provide the reference voltage control signal.

The scan line GW may extend in the first direction DR1. The scan line GW may electrically contact the sixteenth bridge electrode BR16. The scan line GW may provide the scan signal.

Referring to FIG. 10, a sixth conductive layer C6 may be disposed on the fifth conductive layer C5. The sixth conductive layer C6 may include twenty-sixth to thirty bridge electrodes BR26, BR27, BR28-1, BR28-2, BR29, BR30-1, and BR30-2, the emitting initialization control line EB, a horizontal initialization voltage line VINT H, a horizontal power voltage line ELVDD_H, and a second emitting control line EM2.

The twenty-sixth bridge electrode BR26 may electrically contact the nineteenth bridge electrode BR19.

The twenty-seventh bridge electrode BR27 may electrically contact the seventeenth bridge electrode BR17.

The twenty-eight bridge electrode BR28-1 disposed in the first pixel area PXA1 may electrically contact the twenty-fourth bridge electrode BR24-1 disposed in the first pixel area PXA1.

The twenty-eight bridge electrode BR28-2 disposed in the second pixel area PXA2 may electrically contact the twenty-fourth bridge electrode BR24-2 disposed in the second pixel area PXA2.

The twenty-ninth bridge electrode BR29 may electrically contact the twenty-fifth bridge electrode BR25.

The thirty bridge electrode BR30-1 disposed in the first pixel area PXA1 may electrically contact the twenty-third bridge electrode BR23-1 disposed in the first pixel area PXA1.

The thirty bridge electrode BR30-2 disposed in the second pixel area PXA2 may electrically contact the twenty-third bridge electrode BR23-2 disposed in the second pixel area PXA2.

The emitting initialization control line EB may extend in the first direction DR1. The emitting initialization control line EB may electrically contact the eighteenth bridge electrode BR18. The emitting initialization control line EB may provide the emitting initialization control signal.

The horizontal initialization voltage line VINT_H may extend in the first direction DR1. The horizontal initialization voltage line VITN_H may electrically contact the twenty bridge electrodes BR20-1 and BR20-2. The horizontal initialization voltage line VINT_H may provide the initialization voltage.

The horizontal power voltage line ELVDD_H may extend in the first direction DR1. The horizontal power voltage line ELVDD_H may electrically contact the twenty-first bridge electrode BR21. The horizontal power voltage line ELVDD_H may provide the power voltage.

The second emitting control line EM2 may extend in the first direction DR1. The second emitting control line EM2 may electrically contact the twenty-second bridge electrodes BR22-1 and BR22-2. The second emitting control line EM2 may provide the second emitting control signal.

Referring to FIG. 11, a seventh conductive layer C7 may be disposed on the sixth conductive layer C6. The seventh conductive layer C7 may include thirty-first bridge electrodes BR31-1 and BR31-2, a vertical initialization voltage line VINT_V, the bias voltage line VBIAS, the reference voltage line VREF, the vertical power voltage line ELVDD_V, a first data line DATA-1, and a second data line DATA-2.

The thirty-first bridge electrode BR31-1 disposed in the first pixel area PXA1 may electrically contact the thirty bridge electrode BR30-1 disposed in the first pixel area PXA1. The thirty-first bridge electrode BR31-1 may be electrically connected to the anode electrode of light emitting diode EL disposed in the first pixel area PXA1.

The thirty-first bridge electrode BR31-2 disposed in the second pixel area PXA2 may electrically contact the thirty bridge electrode BR30-2 disposed in the second pixel area PXA2. The thirty-first bridge electrode BR31-1 may be electrically connected to the anode electrode of the light emitting diode EL disposed in the second pixel area PXA2.

The vertical initialization voltage line VINT_V may extend in the second direction DR2. The vertical initialization voltage line VINT_V may electrically contact the twenty-sixth bridge electrode BR26. The vertical initialization voltage line VINT_V may provide the initialization voltage.

The bias voltage line VBIAS may extend in the second direction DR2. The bias voltage line VBIAS may electrically contact the twenty-seventh bridge electrode BR27. The bias voltage line VBIAS may provide the bias voltage.

The reference voltage line VREF may extend in the second direction DR2. The reference voltage line VREF may electrically contact the twenty-ninth bridge electrode BR29. The reference voltage line VREF may provide the reference voltage.

The vertical power voltage line ELVDD_V may extend in the second direction DR2. The vertical power voltage line ELVDD_V may electrically contact the horizontal power voltage line ELVDD_H. The vertical power voltage line ELVDD_V may provide the power voltage.

The first data line DATA-1 may extend in the second direction DR2. The first date line DATA1 may electrically contact the twenty-eight bridge electrode BR28-1 disposed in the first pixel area PXA1. The first data line DATA-1 may provide a first data signal.

The second data line DATA-2 may extend in the second direction DR2. The second data line DATA-2 may electrically contact the twenty-eight bridge electrode BR28-2 disposed in the second pixel area PXA2. The second data line DATA-2 may provide a second data signal.

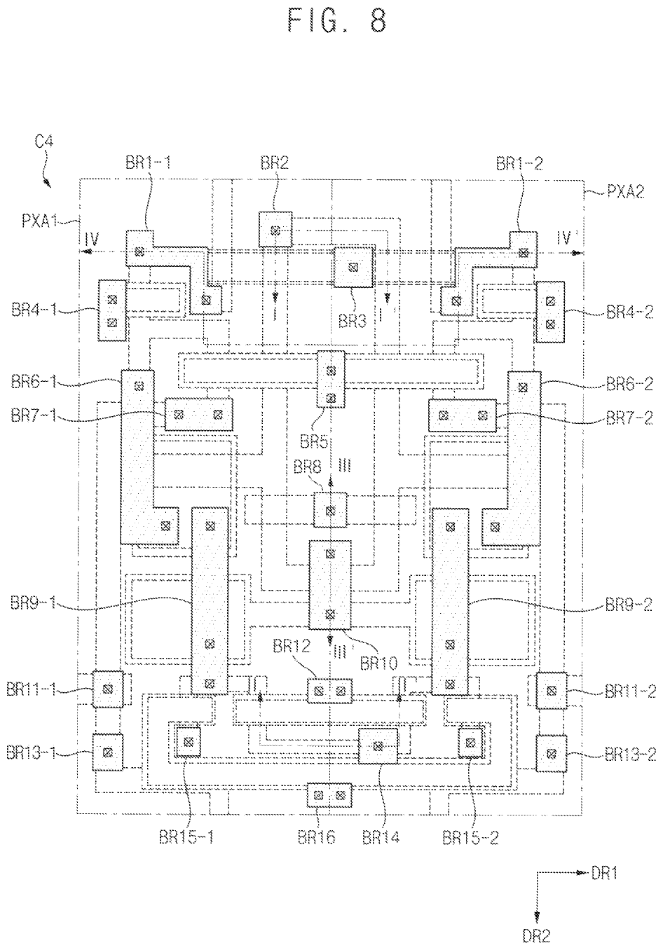

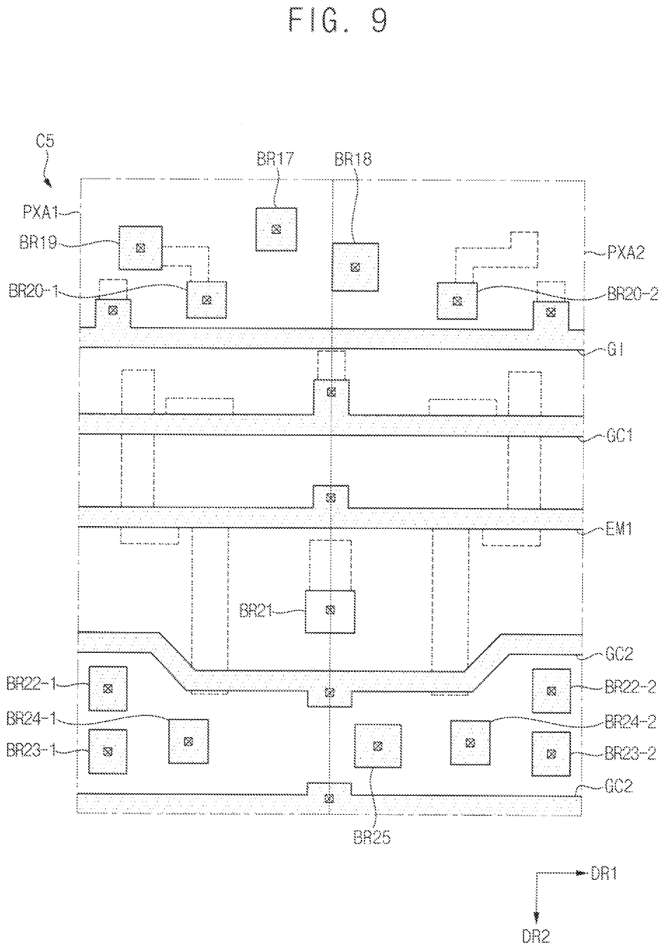

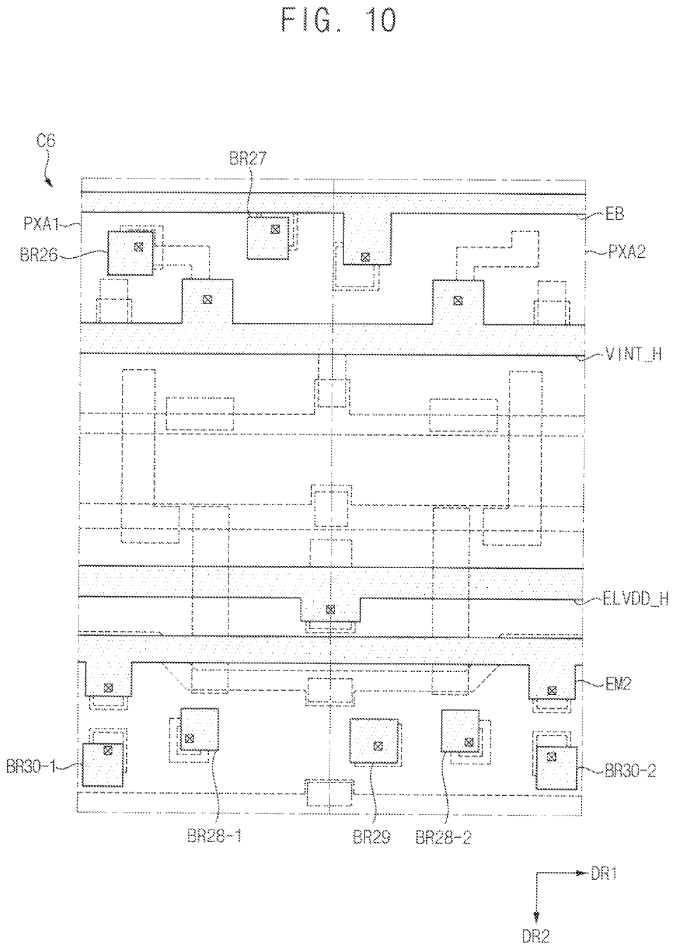

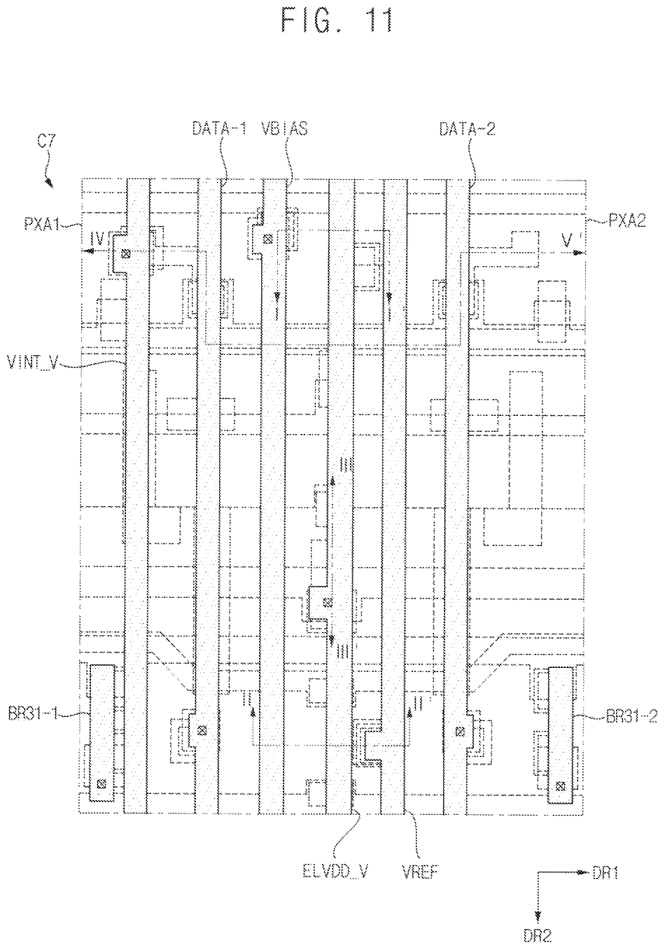

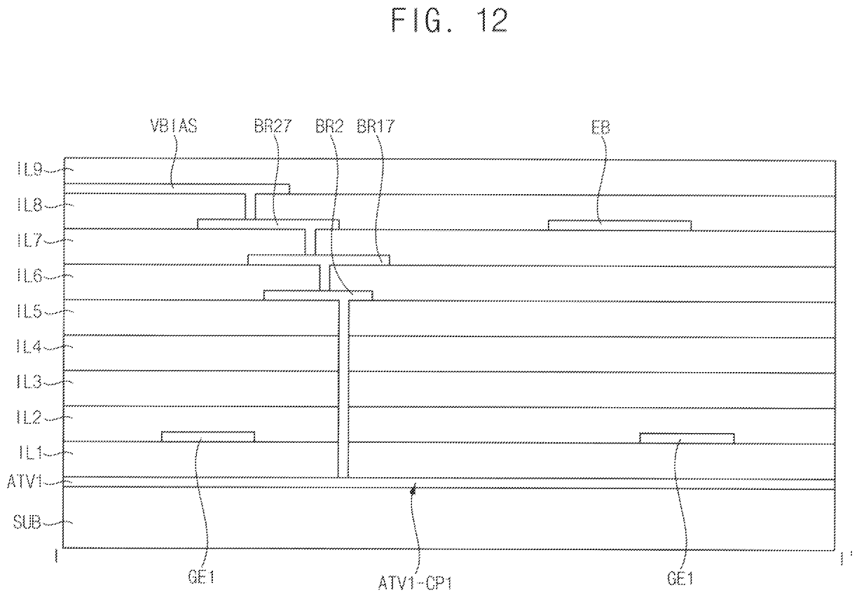

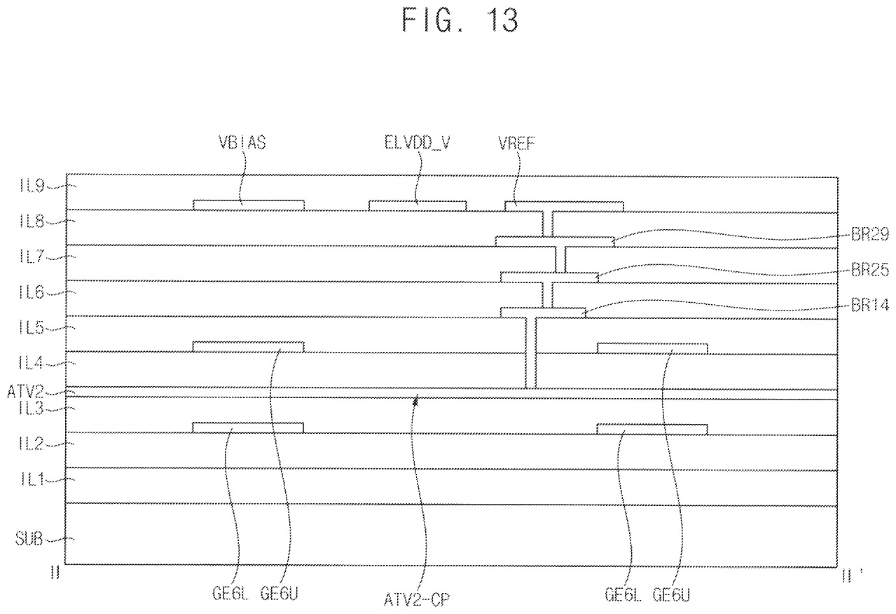

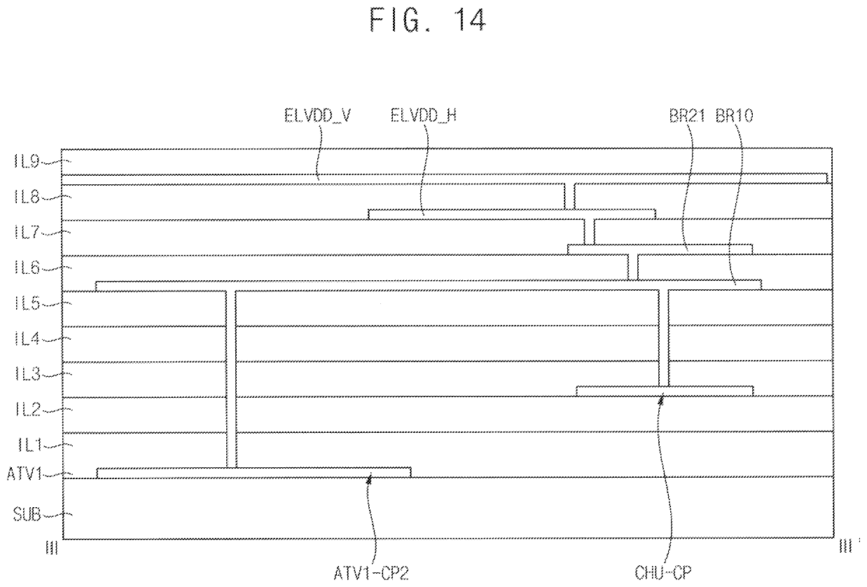

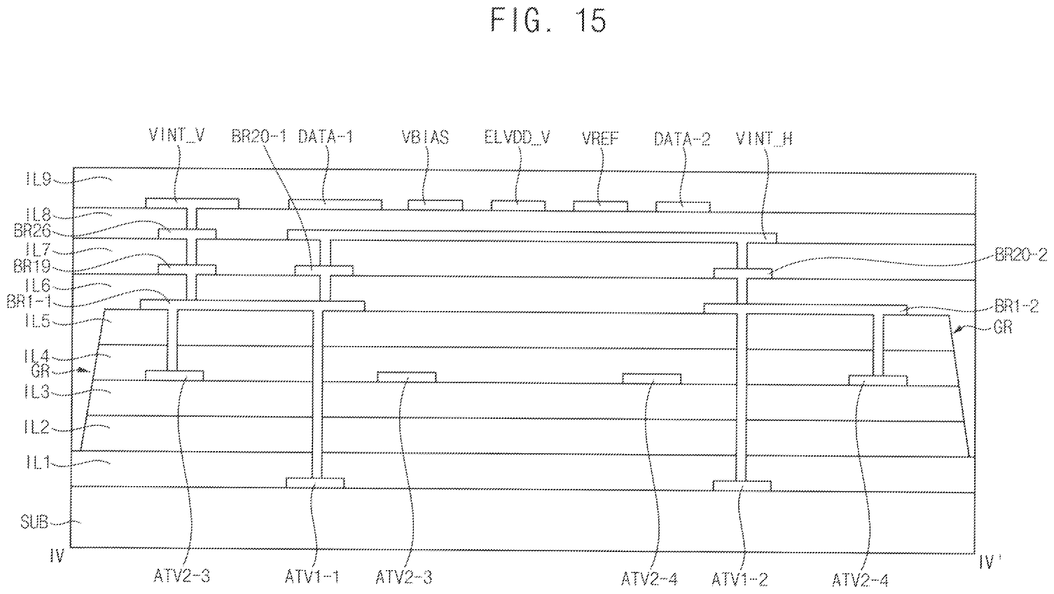

FIG. 12 is a schematic cross-sectional view taken along line I-I′ of FIG. 8 and FIG. 11. FIG. 13 is a schematic cross-sectional view taken along line II-II′ of FIG. 8 and FIG. 11. FIG. 14 is a schematic cross-sectional view taken along line III-III′ of FIG. 8 and FIG. 11. FIG. 15 is a schematic cross-sectional view taken along line IV-IV′ of FIG. 8 AND FIG. 11.

Referring to FIG. 2, FIG. 3, FIG. 4, FIG. 5, FIG. 6, FIG. 7, FIG. 8, FIG. 9, FIG. 10, FIG. 11, FIG. 12, FIG. 13, FIG. 14, and FIG. 15, the display device 1000 according to an embodiment may include a substrate SUB, the first semiconductor layer ATV1, the second semiconductor layer ATV2, the first to seventh conductive layers C1, C2, C3, C4, C5, C6, and C7, and first to ninth insulation layers IL1, IL2, IL3, IL4, IL5, IL6, IL7, IL8, and IL9.

The substrate SUB may include glass. In an embodiment, the substrate SUB may include a material having flexibility, and accordingly, the substrate SUB may have flexibility.

The first semiconductor layer ATV1 may be disposed on the substrate SUB. And, the first insulation layer IL1 may be disposed on the substrate SUB to cover the first semiconductor layer ATV1. The first insulation layer IL1 may include an inorganic insulation material.

The first conductive layer C1 may be disposed on the first insulation layer IL1. And, the second insulation layer IL2 may be disposed on the first insulation layer IL1 to cover the first conductive layer C1. The second insulation layer IL1 may include an inorganic insulation material.

The second conductive layer C2 may be disposed on the second insulation layer IL2. And, the third insulation layer IL3 may be disposed on the second insulation layer IL2 to cover the second conductive layer C2. The third insulation layer IL3 may include an inorganic insulation material.

The second semiconductor layer ATV2 may be disposed on the third insulation layer IL3. And, the fourth insulation layer IL4 may be disposed on the third insulation layer IL3 to cover the second semiconductor layer ATV2. The fourth insulation layer IL4 may include an inorganic insulation material.

The third conductive layer C3 may be disposed on the fourth insulation layer IL4. And, the fifth insulation layer IL5 may be disposed on the fourth insulation layer IL4 to cover the third conductive layer C3. The fifth insulation layer IL5 may include an inorganic insulation material.

The fourth conductive layer C4 may be disposed on the fifth insulation layer IL5. And, the sixth insulation layer IL6 may be disposed on the fifth insulation layer IL5 to cover the fourth conductive layer C4. The sixth insulation layer IL6 may include an organic insulation material, and an upper surface of the sixth insulation layer IL6 may be substantially flat.

The fifth conductive layer C5 may be disposed on the sixth insulation layer IL6. And, the seventh insulation layer IL7 may be disposed on the sixth insulation layer IL6 to cover the fifth conductive layer C5. The seventh insulation layer IL7 may include an organic insulation material, and an upper surface of the seventh insulation layer IL7 may be substantially flat.

The sixth conductive layer C6 may be disposed on the seventh insulation layer IL7. And, the eight insulation layer IL8 may be disposed on the seventh insulation layer IL7 to cover the sixth conductive layer C6. The eight insulation layer IL8 may include an organic insulation material, and an upper surface of the eight insulation layer IL8 may be substantially flat.

The seventh conductive layer C7 may be disposed on the eight insulation layer IL8. The ninth insulation layer IL9 may be disposed on the eight insulation layer IL8 to cover the seventh conductive layer C7. The ninth insulation layer IL9 may include an organic insulation material, and an upper surface of the ninth insulation layer IL9 may be substantially flat.

Referring to FIG. 12, the bias voltage line VBIAS may be electrically connected to the first connection portion ATV1-CP1 of the first semiconductor layer ATV1. In an embodiment, the bias voltage line VBIAS may be electrically connected to the first connection portion ATV1-CP1 of the first semiconductor layer ATV1 through the twenty-seventh bridge electrode BR27, the seventeenth bridge electrode BR17, and the second bridge electrode BR2.

In the disclosure, the first connection portion ATV1-CP1 of the first semiconductor layer ATV1 may be the source area of the first bias transistor T8L and the source area of the second bias transistor T8R, and accordingly, the source area of the first bias transistor T8L and the source area of the second bias transistor T8R may share one bias voltage line VBIAS.

Referring to FIG. 13, the reference voltage line VREF may be electrically connected to the connection portion ATV2-CP of the second semiconductor layer ATV2. In an embodiment, the reference voltage line VREF may be electrically connected to the connection portion ATV2-CP of the second semiconductor layer ATV2 through the twenty-ninth bridge electrode BR29, the twenty-fifth bridge electrode BR25, and the fourteenth bridge electrode BR14.

In the disclosure, the connection portion ATV2-CP of the second semiconductor layer ATV2 may be the drain area of the first reference transistor T5L and the drain area of the second reference transistor T5R, and accordingly, the drain area of the first reference transistor T5L and the drain area of the second reference transistor T5R may share one reference voltage line VREF.

Referring to FIG. 14, the vertical power voltage line ELVDD_V and the horizontal power voltage line ELVDD_H may be electrically connected to the second connection portion ATV1-CP2 of the first semiconductor layer ATV1. In an embodiment, the vertical power voltage line ELVDD_V may be electrically connected to the second connection portion ATV1-CP2 of the first semiconductor layer ATV1 through the horizontal power voltage line ELVDD_H, the twenty-first bridge electrode BR21, and the tenth bridge electrode BR10.

In the disclosure, the second connection portion ATV1-CP2 of the first semiconductor layer ATV1 may be the source area of the first emitting control transistor T9L and the source area of the second emitting control transistor T9R, and accordingly, the first emitting control transistor T9L and the source area of the second emitting control transistor T9R may share one vertical power voltage line ELVDD_V and one horizontal power voltage line ELVDD_H.

The vertical power voltage line ELVDD_V and the horizontal power voltage line ELVDD_H may be electrically connected to the connection portion CHU-CP of the hold capacitor upper electrode CHU. In an embodiment, the vertical power voltage line ELVDD_V may be electrically connected to the connection portion CHU-CP of the hold capacitor upper electrode CHU through the horizontal power voltage line ELVDD_H, the twenty-first bridge electrode BR21, and the tenth bridge electrode BR10.

Accordingly, in the disclosure, the first emitting control transistor T9L, the source area of the second emitting control transistor T9R, and the hold capacitor upper electrode CHU may share one vertical power voltage line ELVDD_V and one horizontal power voltage line ELVDD_H.

Referring to FIG. 15, the vertical initialization voltage line VINT_V and the horizontal initialization voltage line VINT_H may be electrically connected to the first portion ATV1-1 of the first semiconductor layer ATV1, the second portion ATV1-2 of the first semiconductor layer ATV1, the third portion ATV2-3 of the second semiconductor layer ATV2, and the fourth portion ATV2-4 of the second semiconductor layer ATV2.

By way of example, the vertical initialization voltage line VINT_V may be electrically connected to the first bridge electrode BR1-1 disposed in the first pixel area PXA1, and the first bridge electrode BR1-1 disposed in the first pixel area PXA1 may be electrically connected to the first bridge electrode BR1-2 disposed in the second pixel area PXA2 through the horizontal initialization voltage line VINT_H. The first bridge electrode BR1-1 disposed in the first pixel area PXA1 may be electrically connected to the drain area of the first initialization transistor T4L and the source area of the first emitting initialization transistor T7L, and the first bridge electrode BR1-2 disposed in the second pixel area PXA2 may be electrically connected to the drain area of the second initialization transistor T4R and the source area of the second emitting initialization transistor T7R.

Accordingly, in the disclosure, the drain area of the first initialization transistor T4L, the source area of the first emitting initialization transistor T7L, the drain area of the second initialization transistor T4R, and the source area of the second emitting initialization transistor T7R may share one vertical initialization voltage line VINT_V and one horizontal initialization voltage line VINT_H.

In an embodiment, a groove GR may be formed in the first to fifth insulation layers IL1, IL2, IL3, IL4, and IL5. The groove GR may be formed to correspond to the valley area VA described with reference to FIG. 1. In other words, the groove GR may be formed to surround the first pixel area PX1 and the second pixel area PX2.

Although, FIG. 15 illustrates the groove GR formed in the second to fifth insulation layers IL2, IL3, IL4, and IL5 and exposing an upper surface of the first insulation layer IL1, the shape of the groove GR is not limited thereto. For example, the groove GR may be formed in the third to fifth insulation layers IL3, IL4, and IL5 and may be formed to expose an upper surface of the second insulation layer IL2.

An organic insulation material may be filled in the groove GR. For example, the organic insulation material included in the sixth insulation layer IL6 may be filled in the groove GR.

Although embodiments and implementations have been described herein, other embodiments and modifications will be apparent from this description. Accordingly, the disclosure is not limited to such embodiments, but rather to the broader scope of the appended claims and various modifications and equivalent arrangements as would be apparent to a person of ordinary skill in the art.

What is claimed is:

1. A display device, comprising:
a first semiconductor layer disposed on a substrate, and comprising a first portion disposed in a first pixel area, a second portion disposed in a second pixel area, and a first connection portion connecting the first portion and the second portion, and the first portion and the second portion have a shape symmetrical to each other based on a boundary between the first pixel area and the second pixel area;
a second semiconductor layer disposed on the first semiconductor layer, and comprising a first portion disposed in the first pixel area, a second portion disposed in the second pixel area, and a connection portion connecting the first portion and the second portion, and the first portion and the second portion have a shape symmetrical to each other based on the boundary between the first pixel area and the second pixel area;
a bias voltage line disposed on the second semiconductor layer, electrically connected to the first connection portion of the first semiconductor layer, and extending in a second direction intersecting a first direction; and
a reference voltage line disposed on the second semiconductor layer, electrically connected to the connection portion of the second semiconductor layer, and extending in the second direction.

2. The display device of claim 1, further comprising:
a first gate electrode disposed on the first semiconductor layer, wherein
a portion of the first gate electrode overlaps the first portion of the first semiconductor layer to define a first bias transistor in a plan view, and another portion of the first gate electrode overlaps the second portion of the first semiconductor layer to define a second bias transistor in the plan view.

3. The display device of claim 2, wherein the first connection portion of the first semiconductor layer is a source area of the first bias transistor and a source area of the second bias transistor.

4. The display device of claim 2, further comprising:
an emitting initialization control line disposed on the second semiconductor layer, extending in the first direction, and electrically connected to the first gate electrode.

5. The display device of claim 1, further comprising:
an upper gate electrode disposed on the second semiconductor layer, a portion of the upper gate electrode overlaps the first portion of the second semiconductor layer to define a first reference transistor in a plan view, and another portion of the upper gate electrode overlaps the second portion of the second semiconductor layer to define a second reference transistor in the plan view.

6. The display device of claim 5, further comprising:
a lower gate electrode disposed below the second semiconductor layer, a portion of the lower gate electrode overlaps the first portion of the second semiconductor layer and the portion of the upper gate electrode in the plan view, and another portion of the lower gate electrode overlaps the second portion of the second semiconductor layer and the another portion of the upper gate electrode in the plan view.

7. The display device of claim 5, wherein the connection portion of the second semiconductor layer is a drain area of the first reference transistor and a drain area of the second reference transistor.

8. The display device of claim 5, further comprising:
a reference voltage control line disposed on the second semiconductor layer, extending in the first direction, and electrically connected to the upper gate electrode.

9. The display device of claim 1, wherein the first semiconductor layer comprises a silicon semiconductor, and the second semiconductor layer comprises an oxide semiconductor.

10. The display device of claim 1, further comprising:
an inorganic insulation layer disposed between the first semiconductor layer and the bias voltage line, and having a groove surrounding the first pixel area and the second pixel area.

11. The display device of claim 10, further comprising:
an organic insulation layer disposed on the inorganic insulation layer, and filling the groove of the inorganic insulation layer.

12. A display device, comprising:
a first semiconductor layer disposed on a substrate, and comprising a first portion disposed in a first pixel area, a second portion disposed in a second pixel area, and a first connection portion connecting the first portion and the second portion, the first portion and the second portion have a shape symmetrical to each other based on a boundary between the first pixel area and the second pixel area;
a second semiconductor layer disposed on the first semiconductor layer, and comprising a first portion disposed in the first pixel area, a second portion disposed in the second pixel area, a connection portion connecting the first portion and the second portion, a third portion disposed in the first pixel area, and a fourth portion disposed in the second pixel area and spaced apart from the third portion, the first portion and the second portion have a shape symmetrical to each other based on the boundary between the first pixel area and the second pixel area, and the third portion and the fourth portion have a shape symmetrical to each other based on the boundary between the first pixel area and the second pixel area;
a reference voltage line disposed on the second semiconductor layer, electrically connected to the connection portion of the second semiconductor layer, and extending in the second direction; and
an initialization voltage line disposed on the second semiconductor layer, and electrically connected to the third portion of the second semiconductor layer and the fourth portion of the second semiconductor layer.

13. The display device of claim 12, wherein the initialization voltage line comprises:
a horizontal initialization voltage line electrically connected to the third portion of the second semiconductor layer and the fourth portion of the second semiconductor layer, and extending in the first direction; and
a vertical initialization voltage line electrically connected to the third portion of the second semiconductor layer.

14. The display device of claim 13, further comprising:
a first bridge electrode disposed on the second semiconductor layer, electrically connecting the third portion of the second semiconductor layer and the first portion of the first semiconductor layer, and electrically connected to each of the horizontal initialization voltage line and the vertical initialization voltage line; and
a second bridge electrode disposed on the second semiconductor layer, electrically connecting the fourth portion of the second semiconductor layer and the second portion of the first semiconductor layer, and electrically connected to the horizontal initialization voltage line.

15. A display device, comprising:
a first semiconductor layer disposed on a substrate, and comprising a first portion disposed in a first pixel area, a second portion disposed in a second pixel area, a first connection portion connecting the first portion and the second portion, and a second connection portion connecting the first portion and the second portion and spaced apart from the first connection portion, the first portion and the second portion have a shape symmetrical to each other based on a boundary between the first pixel area and the second pixel area;
a bias voltage line disposed on the first semiconductor layer, electrically connected to the first connection portion of the first semiconductor layer, and extending in a second direction intersecting the first direction; and
a power voltage line disposed on the first semiconductor layer, and electrically connected to the second connection portion of the first semiconductor layer.

16. The display device of claim 15, wherein the power voltage line further comprises:
a horizontal power voltage line electrically connected to the second connection portion of the first semiconductor layer, and extending in the first direction; and
a vertical power voltage line electrically contacting the horizontal power voltage line, and extending in the second direction.

17. The display device of claim 15, further comprising:
a second gate electrode disposed on the first semiconductor layer,
a portion of the second gate electrode overlaps the first portion of the first semiconductor layer to define a first emitting control transistor in a plan view, and another portion of the second gate electrode overlaps the second portion of the first semiconductor to define a second emitting control transistor in the plan view.

18. The display device of claim 17, wherein the second connection portion of the first semiconductor layer is a source area of the first emitting control transistor and a source area of the second emitting control transistor.

19. The display device of claim 17, further comprising:
a first hold capacitor lower electrode disposed in the first pixel area, and spaced apart from the second gate electrode;
a second hold capacitor lower electrode disposed in the second pixel area, and spaced apart from the second gate electrode and the first hold capacitor lower electrode, the first hold capacitor lower electrode and the second hold capacitor lower electrode have a shape symmetrical to each other based on the boundary between the first pixel area and the second pixel area; and
a hold capacitor upper electrode disposed on the first hold capacitor lower electrode and the second hold capacitor lower electrode, and comprising a first portion overlapping the first hold capacitor lower electrode in a plan view, a second portion overlapping the second hold capacitor lower electrode in the plan view, and a connection portion connecting the first portion and the second portion.

20. The display device of claim 19, further comprising:
a bridge electrode disposed on the hold capacitor upper electrode, connecting the hold capacitor upper electrode and the second connection portion of the first semiconductor layer, and electrically connected to the power voltage line.
